(19) United States
(12) Patent Application Publication
(10) Pub. No.: US 2024/0088329 A1
(43) Pub. Date: Mar. 14, 2024

(54) DISPLAY MODULE COMPRISING JUNCTION STRUCTURE BETWEEN MICRO LED AND TFT LAYER

(71) Applicant: SAMSUNG ELECTRONICS CO., LTD., Suwon-si (KR)

(72) Inventors: Eunhye KIM, Suwons-si (KR); Sangmoo Park, Suwon-si (KR); Dongyeob Lee, Suwon-si (KR); Yoonsuk Lee, Suwon-si (KR)

(73) Assignee: SAMSUNG ELECTRONICS CO., LTD., Suwon-si (KR)

(21) Appl. No.: 17/941,695

(22) Filed: Sep. 9, 2022

Related U.S. Application Data
(63) Continuation of application No. PCT/KR2021/005357, filed on Apr. 28, 2021.

(30) Foreign Application Priority Data
Apr. 29, 2020 (KR) 10-2020-0052816

(51) Int. Cl. H01L 33/40; H01L 25/075; H01L 33/62

(52) U.S. Cl. CPC H01L 33/40; H01L 25/0753; H01L 33/62

(57) ABSTRACT

A display module includes a thin film transistor (TFT) substrate including a glass substrate, a TFT layer provided at a front surface of the glass substrate and comprising a TFT electrode pad, and a driving circuit provided at a rear surface of the glass substrate and configured to drive the TFT layer, at least one light-emitting diode (LED) comprising at least one LED electrode pad, and a junction structure provided between the at least one LED electrode pad and the TFT electrode pad. The junction structure is formed in a metallically bonded state.

### CROSS-REFERENCE TO RELATED APPLICATION(S)

This application is a bypass continuation of International Application No. PCT/KR2021/005357, filed on Apr. 28, 2021, in the Korean Intellectual Property Receiving Office, which is based on and claims priority to Korean Patent Application No. 10-2020-0052816, filed on Apr. 29, 2020, in the Korean Intellectual Property Office, the disclosures of which are incorporated by reference herein in their entireties.

### BACKGROUND

### 1. Field

The disclosure relates to a display module, and more particularly to a display module having a junction structure by mutual metallic bonding of an electrode pad of a micro light-emitting diode (LED) and a thin-film transistor (TFT) electrode pad.

### 2. Description of Related Art

Light-emitting diodes (LEDs) are used not only as light sources for lighting devices, but also widely used as light sources for various display devices of various electronic products such as, for example, and without limitation, a television (TV), a mobile phone, a personal computer (PC), a notebook PC, a personal digital assistant (PDA), and the like.

In particular, recently, micro LEDs which are less than or equal to 100 mm in its size are under development, and the micro LEDs are attracting much attention as light-emitting elements of next generation displays having a faster response rate, lower energy consumption and higher brightness compared to LEDs of the related art.

As described above, the micro LEDs are transferred to a thin-film transistor (TFT) layer formed on a glass substrate. In this case, the micro LEDs may be configured such that provided electrodes (an anode electrode and a cathode electrode) are electrically connected to electrodes formed on the TFT layer.

In this case, the TFT electrode is stacked, in most cases, with an oxide film to prevent oxidization. However, when the TFT electrode is covered with the oxide film as described above, there may be an electrical connection by an anisotropic conductive film (ACF) of a thin film disposed between an LED electrode and a TFT electrode.

However, if the oxide film is present between the micro LED electrode and the TFT electrode, bonding through metallic bonding between the micro LED electrode and the TFT electrode may not be possible.

### SUMMARY

Provided is a display module having a junction structure through metallic bonding through which a new metal compound is generated with a micro LED electrode pad and a TFT electrode pad.

Additional aspects will be set forth in part in the description which follows and, in part, will be apparent from the description, or may be learned by practice of the presented embodiments.

According to an aspect of the disclosure, a display module may include a thin film transistor (TFT) substrate including a glass substrate, a TFT layer provided at a front surface of the glass substrate and comprising a TFT electrode pad, and a driving circuit provided at a rear surface of the glass substrate and configured to drive the TFT layer, at least one light-emitting diode (LED) comprising at least one LED electrode pad, and a junction structure provided between the at least one LED electrode pad and the TFT electrode pad. The junction structure may be formed in a metallically bonded state.

At least one of the LED electrode pad and the TFT electrode pad may further include a solder layer.

The LED electrode pad may include a barrier layer including at least one from among Au, Ni, Ti, Cr, Pd, TiN, Ta, TiW, TaN, AlSiTiN, NiTi, TiBN, ZrBN, TiAlN, and TiB₂, and the TFT electrode pad may include at least one from among Au, Cu, Ag, Ni, Ni/Au, Au/Ni, Ni/Cu, and Cu/Ni.

The solder layer may include Sn or In.

A capping layer may be provided at an upper part of the solder layer, and the capping layer may include Au.

The solder layer may include at least two from among Sn, Ag, In, Cu, Ni, Au, Bi, Al, Zn, and Ga.

A capping layer may be provided at an upper part of the solder layer, and the capping layer may include Au.

The LED electrode pad may include a filler layer provided at the barrier layer, the filler layer may be provided between semiconductor layer of the at least one LED and the barrier layer, and the filler layer may include one from among Au, Cu, Ni, and Al.

A thickness of the LED electrode pad may be less than or equal to 40% of a thickness of the at least one LED.

A thickness of the barrier layer may be about 0.05 μm to about 2 μm, a thickness of the solder layer is about 0.4 μm to about 2 μm, and a thickness of the filler layer is about 1 μm to about 5 μm.

A thickness of the TFT electrode pad may be about 0.1 μm to about 1 μm.

An interval between LEDs adjacent to one another may be about 20 to about 70% of a size of the at least one LED.

The TFT electrode pad may be provided on the TFT layer.

The TFT electrode pad may include Au or Ni, and the TFT electrode pad may be formed on the TFT layer in an electrolytic plating method.

According to an aspect of the disclosure, a display module may include a TFT substrate including a glass substrate, a TFT layer provided at a front surface of the glass substrate, and a driving circuit provided at a rear surface of the glass substrate and configured to drive the TFT layer, a plurality of LEDs, and a pair of LED electrode pads provided for each LED of the plurality of LEDs. Each of the pair of LED electrode pads may include a junction structure in a metallically bonded state, and an interval between LEDs of the plurality of LEDs adjacent to one another may be determined based on a minimum distance between the pair of LED electrode pads.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a diagram illustrating schematically a display module according to an embodiment;

FIG. 2 is a schematic diagram illustrating pixels arrayed on a thin-film transistor (TFT) layer according to an embodiment;

FIG. 3 is a cross-sectional diagram illustrating schematically a display module according to an embodiment;

FIG. 4A is a cross-sectional diagram illustrating schematically a micro light-emitting diode (LED) according to an embodiment;

FIG. 4B is a diagram illustrating an example in which a capping layer is additionally formed on a solder layer of each LED electrode pad shown in FIG. 4A according to an embodiment;

FIG. 5 is a cross-sectional diagram illustrating schematically a TFT substrate according to an embodiment;

FIG. 6 is a cross-sectional diagram illustrating a junction structure between a micro LED and a TFT substrate according to an embodiment;

FIG. 7 is a cross-sectional diagram illustrating schematically a micro LED according to an embodiment;

FIG. 8 is a cross-sectional diagram illustrating schematically a micro LED according to an embodiment;

FIG. 9A is a cross-sectional diagram illustrating schematically a TFT substrate according to an embodiment;

FIG. 9B is a diagram illustrating an example in which a capping layer is additionally formed on a solder layer of each TFT electrode pad shown in FIG. 9A according to an embodiment;

FIGS. 10A, 10B and 10C are diagrams illustrating various embodiments on two electrode pads of a micro LED according to an embodiment;

FIG. 11 is a cross-sectional diagram illustrating schematically a micro LED according to an embodiment;

FIG. 12 is a diagram illustrating a micro LED of a vertical type formed in a circular shape according to an embodiment;

FIG. 13 is a block diagram illustrating schematically a laser transfer device according to an embodiment; and

FIG. 14 is a block diagram illustrating schematically a laser oscillator of a laser transfer device according to an embodiment.

### DETAILED DESCRIPTION

Various embodiments will be described in greater detail below with reference to the accompanied drawings. The embodiments described herein may be variously modified. Specific embodiments may be depicted in the drawings and described in detail in the detailed description. However, the specific embodiments described in the accompanied drawings are merely to assist in the understanding of various embodiments. Accordingly, the technical spirit is not to be limited by the specific embodiments described in the accompanied drawings, and should be interpreted to include all equivalents or alternatives of the embodiments included in the idea and the technical scope disclosed herein.

Terms including ordinals such as “first,” and “second” may be used in describing the various elements, but the elements are not to be limited by the above-described terms. The above-described terms may be used only to distinguish one element from another.

In the disclosure, expressions such as “comprise,” “include” or the like are used to designate a presence of a characteristic, number, step, operation, element, component, or a combination thereof, and not to preclude a presence or a possibility of adding one or more of other characteristics, numbers, steps, operations, elements, components or a combination thereof.

In addition thereto, in describing the disclosure, in case it is determined that the detailed description of related known technologies may unnecessarily confuse the gist of the disclosure, the detailed description thereof will be omitted.

A glass substrate may be disposed with a thin-film transistor (TFT) layer on which a TFT circuit is formed at a front surface, and disposed with a driving circuit for driving the TFT circuit of the TFT layer at a back surface. The glass substrate may be formed in a quadrangle type. Specifically, the glass substrate may be formed as a rectangle or a square.

A substrate on which the TFT layer (or backplane) is stacked on the glass substrate may be referred to as a TFT substrate. The TFT substrate may not limited to a specific structure or type. For example, the TFT referred in the disclosure may be implemented as, for example, and without limitation, an oxide TFT, a Si TFT (poly silicon, a-silicon), an organic TFT, a graphene TFT, and the like in addition to a low-temperature polycrystalline silicon (LTPS) TFT, and may be applied by manufacturing only a P-type (or N-type) metal oxide semiconductor field effect transistor (MOSFET) in a Si wafer complementary metal oxide semiconductor (CMOS) process.

The front surface of the glass substrate on which the TFT layer is disposed may be divided into an active area and an inactive area. The active area may correspond to an area occupied by the TFT layer at one surface of the glass substrate, and the inactive area may correspond to an edge area at one surface of the glass substrate.

The edge area of the glass substrate may include a side surface of the glass substrate. In addition, the edge area of the glass substrate may be a remaining area except for an area to which the TFT circuit is disposed at the front surface of the glass substrate and an area to which the driving circuit disposed at the back surface is disposed. In addition, the edge area of the glass substrate may include the side surface of the glass substrate with a portion of the front surface of the glass substrate and a portion of the back surface of the glass substrate which are adjacent to the side surface thereof.

The glass substrate may be formed with multiple front surface connection pads which are electrically connected with the TFT circuit through wiring at the edge area of the front surface and multiple back surface connection pads which are electrically connected with the driving circuit through wiring at the edge area of the back surface. The multiple front surface and back surface connection pads may be disposed to be inserted by a certain distance from the side surface of the glass substrate to the inner side of the glass substrate. The connection pads which are each formed at the front surface and the back surface of the glass substrate may be electrically connected by side surface wiring which is formed at the edge area of the glass substrate.

The TFT layer of the glass substrate may be provided with multiple pixels. Each pixel may be formed of multiple sub pixels, and one sub pixel may correspond to one micro light-emitting diode (LED). The TFT layer may include a TFT circuit for driving each pixel. The micro LED may include inorganic light-emitting materials, and may be a semiconductor chip capable of emitting light on its own when a power source is provided. In addition, the micro LED may have a flip chip structure in which anode and cathode electrodes are formed at a same surface and a light-emitting surface is formed at an opposite side of the electrodes.

The TFT layer stacked and formed on the glass substrate may be electrically connected to the micro LED. Specifically, the electrode pad of the micro LED may be electrically connected to the electrode pad on the TFT layer, and the electrode of the micro LED and the TFT electrode may have a junction structure in a metallically bonded state.

A display module which includes micro LEDs or μLED may be a flat display panel. The micro LED may be inorganic LEDs having a size of less than or equal to 100 mm. As described above, the display module which includes micro LEDs may provide better contrast, faster response time, and higher energy efficiency compared to a liquid crystal display (LCD) panel which requires a backlight. Organic LEDs (OLEDs) and micro LEDs which are inorganic light-emitting devices may both have good energy efficiency, but the micro LEDs may be brighter, have better light-emitting efficiency, and longer lifespan than the OLED.

The display module may form a black matrix in between the multiple micro LEDs arrayed on the TFT layer. The black matrix may enhance a contrast ratio by blocking light from leaking from a periphery of the micro LEDs adjacent with one another.

The display module may further include a touch screen panel which is disposed to a side at which multiple micro LEDs emit light, and in this case, a touch screen driving part for driving the touch screen panel may be included. In addition, the display module may be disposed at the back surface of the glass substrate and further include a rear substrate which is electrically connected through a flexible printed circuit board (FPCB), and the like. In addition, the display module may further include a communication device capable of receiving data.

As described above, the glass substrate on which the micro LED is mounted and the side surface wiring is formed may be referred to as the display module. The display module as described above may be a single unit, and installed and applied to a wearable device, a portable device, a handheld device, and electronic products which require various displays or in electric fields, and applied to display devices such as, for example, and without limitation, a monitor for a personal computer (PC), a high-resolution television (TV), signage (or, digital signage), an electronic display, and the like through a plurality of assembly dispositions in a matrix type.

The display module according to an embodiment of the disclosure will be described in detail below with reference to the drawings.

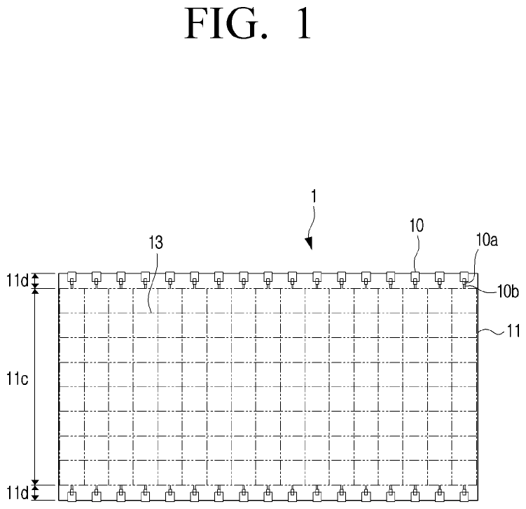

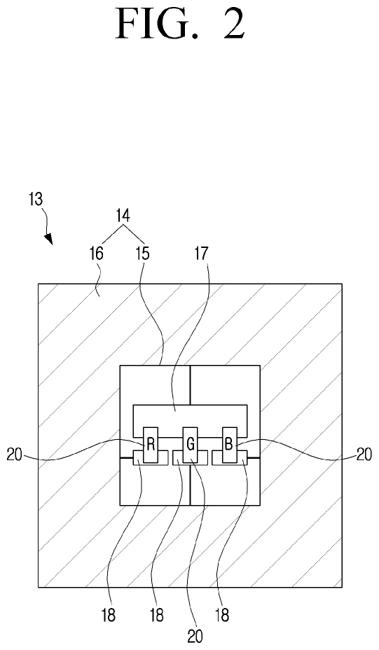

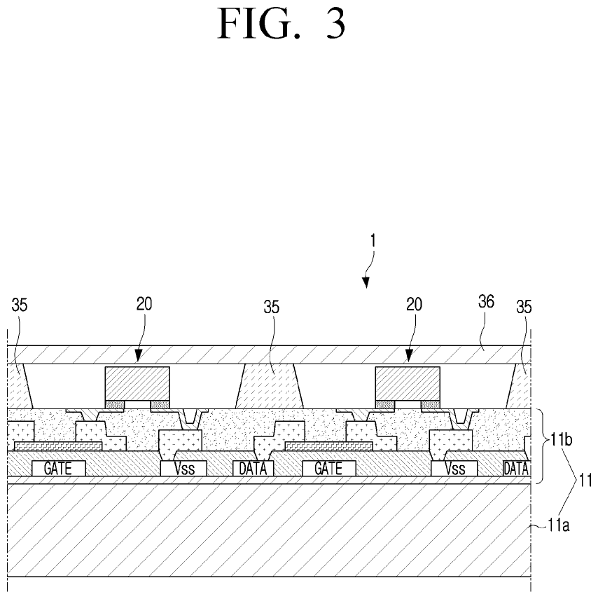

FIG. 1 is a diagram illustrating schematically a display module according to an embodiment. FIG. 2 is a schematic diagram illustrating pixels arrayed on a thin-film transistor (TFT) layer according to an embodiment. FIG. 3 is a cross-sectional diagram illustrating schematically a display module according to an embodiment.

Referring to FIGS. 1 to 3, the display module according to the disclosure may include a TFT substrate 11.

The display module 1 may include multiple micro light-emitting diodes (micro LEDs) 20 which are transferred on the TFT substrate 11. The TFT substrate 11 may include a glass substrate 11a, a TFT layer 11b included with a thin film transistor (TFT) circuit at the front surface of the glass substrate 11a, and multiple side surface wirings 10 which electrically connect the TFT circuit of the TFT layer 11b and circuits disposed at the back surface of the glass substrate 11a. The TFT substrate 11 may include an active area 11c at which an image is represented and an inactive area 11d at which an image cannot be represented at the front surface.

The active area 11c may be divided into multiple pixel areas 13 at which multiple pixels 20 are each arrayed.

The multiple pixel areas 13 may be divided into various forms, and in an example, may be divided in a matrix form. Each pixel area 13 may include a sub pixel area 15 at which multiple pixels (i.e., red LEDs, green LEDs, and blue LEDs) are mounted and a pixel circuit area 16 for driving each sub pixel.

The multiple micro LEDs 20 may be transferred to the pixel circuit area 16 of the TFT layer 11b, and the electrode pads of each micro LED may be electrically connected to the electrode pads 17 and 18 formed on the TFT layer 11b, respectively. A common electrode pad 17 may be formed in a straight-line form taking into considering an array of three micro LEDs 20 which are arrayed in parallel.

The pixel driving method of the display module 1 according to an embodiment of the disclosure may be an active matrix (AM) driving method or a passive matrix (PM) driving method. The display module 1 may form a wiring pattern to which each micro LED is electrically connected according to the AM driving method or the PM driving method.

The inactive area 11d may correspond to the edge area of the TFT substrate 11, and multiple connection pads 10a may be disposed with certain intervals therebetween.

The TFT substrate 11 may be configured such that the multiple connection pads 10a are formed with intervals therebetween in the inactive area 11d. The multiple connection pads 10a may be electrically connected with each sub pixel through wiring 10b, respectively. The multiple connection pads 10a may be respectively disposed at the edge area of the front surface and the edge area of the back surface of the TFT substrate 11.

A number of connection pads 10a which are formed in the inactive area 11d may vary according to a number of pixels implemented to the glass substrate, and vary according to the driving method of the TFT circuit disposed in the active area 11c. For example, the AM driving method which drives each pixel individually may require more wiring and connection pads compared to when the TFT circuit disposed in the active area 110a is the PM driving method which drives multiple pixels in a horizontal line and a vertical line.

In FIG. 3, only two sub pixels from among the micro LEDs 20 which are three sub pixels included in a unit pixel have been shown for convenience.

The display module 1 may be configured such that the multiple micro LEDs 20 may be respectively divided by the black matrix 35, and a transparent cover layer 36 for protecting both the multiple micro LEDs 20 and the black matrix 35 may be provided. In this case, a touch screen panel may be stacked and disposed at one surface of the transparent cover layer 36.

The multiple micro LEDs 20 may include inorganic light-emitting materials, and may be a semiconductor chip capable of emitting light on its own when a power source is provided.

The multiple micro LEDs 20 may have a predetermined thickness and may be formed as a square with a same depth and length, or a rectangle with a different depth and length. The micro LED described above may implement real high dynamic range (HDR), and provide an increase in brightness relative to OLED and black expressiveness and a high contrast ratio. The size of the micro LED may be less than or equal to 100 μm or preferably, less than or equal to 30 μm.

The multiple micro LEDs 20 may have the flip chip structure in which anode and cathode electrodes are formed at the same surface and a light-emitting surface is formed at an opposite side of the electrodes.

An electrically connecting structure of the electrode pads of the micro LED with the electrode pads of the TFT layer will be described below with reference to the drawings. The TFT layer 11b may be formed with multiple TFT electrode pads to which electrode pads of multiple micro LEDs are bonded. In the disclosure, a structure of two electrode pads (hereinafter, referred to as ‘first and second LED electrode pads’) provided in one micro LED being electrically connected to two electrode pads (hereinafter, referred to as ‘first and second TFT electrode pads’) formed on the TFT layer, respectively, will be described for convenience of description.

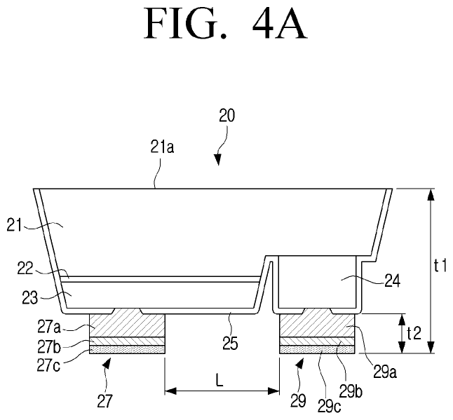

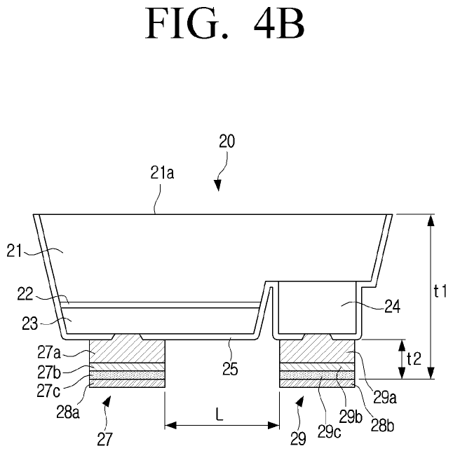

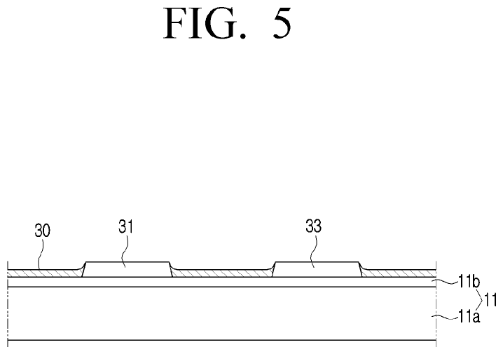

FIG. 4A is a cross-sectional diagram illustrating schematically a micro LED according to an embodiment. FIG. 4B is a diagram illustrating an example in which a capping layer is additionally formed on a solder layer of each LED electrode pad shown in FIG. 4A. FIG. 5 is a cross-sectional diagram illustrating schematically a TFT substrate according to an embodiment.

Referring to FIG. 4A, the micro LED 20 according to the disclosure may have the flip chip structure in which the first and second LED electrode pads 27 and 29 are disposed at one surface of an opposite side of the light-emitting surface. The one surface of the micro LED 20 disposed with the first and second LED electrode pads 27 and 29 may not necessarily need to be a same flat surface, and may be surfaces facing a same direction and having heights different from one another.

The micro LED 20 may include an n-type semiconductor layer 21, a light-emitting layer 22, and a p-type semiconductor layer 23 which are consecutively stacked. In addition, the micro LED 20 may include an n-type ohmic contact 24, an insulation layer 25, and the first and second LED electrode pads 27 and 29.

The light-emitting layer 22 may be multi quantum wells (MQWs) which are well structures that alternately stack the light-emitting layer (active layer) and the insulation layer of a thin film.

The n-type semiconductor layer 21 may be formed wider than the p-type semiconductor layer 23, and the n-type ohmic contact 24 may be stacked in an area at which the light-emitting layer 22 is not formed. The n-type ohmic contact 24 may be formed to a thickness of an extent that one surface is positioned at a same level as one surface of the p-type semiconductor layer 23.

On one surface of the p-type semiconductor layer 23, a first LED electrode pad 27 may be stacked. On one surface of the n-type ohmic contact 24, a second LED electrode pad 29 may be stacked.

The insulation layer 25 may cover the remaining parts excluding the light-emitting surface 21a of the n-type semiconductor layer 21 and the first and second LED electrode pads 27 and 29. The insulation layer 25 may be referred to as a barrier layer or a protection layer.

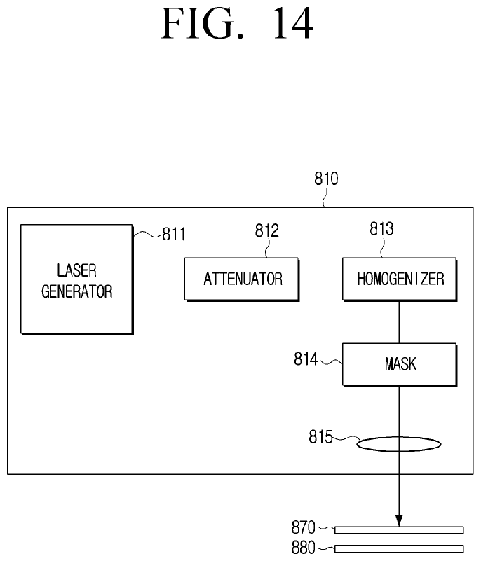

The first and second LED electrode pads 27 and 29 may be electrically connected to the first and second TFT electrode pads 31 and 33 of the TFT layer 11b, respectively. In order to connect each of the LED electrode pads 27 and 29 to each of the TFT electrode pads 31 and 33, a process of pressing the micro LED 20 toward a target substrate 880 (referring to FIG. 14) by a predetermined pressure while applying heat of a predetermined temperature to the micro LED 20 and the TFT layer 11b may be carried out.

Accordingly, the first LED electrode pad 27 and the first TFT electrode pad 31 may be connected in the metallically bonded state, and likewise, the second LED electrode pad 29 and the second TFT electrode pad 33 may be connected in the metallically bonded state. Here, the ‘metallically bonded state’ may refer to a new metallic compound (inter-metallic compound (IMC)) being formed by interacting as a metal material forming the first and second LED electrode pads 27 and 29 and a metal material forming the first and second TFT electrode pads 31 and 33 are heated. The metallically bonded state may be formed by a transient liquid phase (TLP) bonding process.

The LED electrode pad and the TFT electrode pad which are inter-bonded by the TLP bonding process may significantly reduce conformational change after bonding and have advantages such as easy bonding even for different metals which are different in thickness or different in physical properties and have a small heat affected zone. Accordingly, a bonding reliability between the LED electrode pad and the TFT electrode pad having a fine size of less than or equal to 100 μm may be significantly enhanced.

Because the first LED electrode pad 27 and the second LED electrode pad 29 are comprised of the same structure and material, the structure and material of the first LED electrode pad 27 may be mainly described below.

The first LED electrode pad 27 may include a filler layer 27a stacked to the p-type semiconductor layer 23, a barrier layer 27b stacked to the filler layer 27a, and the solder layer 27c stacked to the barrier layer 27b.

The filler layer 27a may reduce a contact resistance between the p-type semiconductor layer 23 and the barrier layer 27b, and enhance an adhesive force between the p-type semiconductor layer 23 and the barrier layer 27b. The filler layer 27a may be formed of any one material from among Au, Cu, Ni, and Al. The filler layer 29a of the second LED electrode pad 29 may reduce the contact resistance between the n-type ohmic contact 24 and the barrier layer 29b, and enhance the adhesive force between the n-type ohmic contact 24 and the barrier layer 29b.

The barrier layer 27b may be formed of any one material from among Au, Ni, Ti, Cr, Pd, TiN, Ta, TiW, TaN, AlSiTiN, NiTi, TiBN, ZrBN, TiAlN, and TiB₂.

The solder layer 27c may include Sn or In for the bonding between the barrier layer 27b and the first TFT electrode pad 31 which will be described below to be smooth or formed of a composition of at least two from among Sn, Ag, In, Cu, Ni, Au, Cu, Bi, Al, Zn, and Ga.

Referring to FIG. 4B, an upper part of the solder layer 27c may be additionally stacked with a capping layer 28a which covers the solder layer 27c to prevent oxidization of the solder layer 27c. In addition, a second electrode pad 29 may also be configured such that an upper part of the solder layer 29c is additionally stacked with a capping layer 28b which covers the solder layer 29c to prevent oxidization of the solder layer 29c. In this case, the material of the capping layers 28a and 28b may be Au and the thickness may be less than or equal to 100 nm.

The filler layer 27a may determine the thickness of the first LED electrode pad 27, and may be formed in a thickness of 1-5 mm. The thickness of the barrier layer 27b may be 0.05-2 μm, and the thickness of the solder layer 27c may be 0.4-2 mm.

A thickness t2 of the first and second LED electrode pads 27 and 29 may be less than or equal to 40% relating to a thickness t1 of the micro LED 20 to prevent a short between the electrode pads of the adjacent micro LED by the solder layers 27c and 29c which are melt when performing the TLP bonding process.

Referring to FIG. 5, the first and second TFT electrode pads 31 and 33 formed at the TFT layer 11b may be electrically connected to a TFT circuit included on the TFT layer 11b. The first and second TFT electrode pads 31 and 33 may not be mutually shorted, and spaced apart at an interval to an extent the first and second TFT electrode pads 31 and 33 may be respectively connected with the first and second LED electrode pads 27 and 29.

For example, the interval between the first and second TFT electrode pads 31 and 33 may correspond to an interval L of the first and second LED electrode pads 27 and 29. In this case, the first and second TFT electrode pads 31 and 33 may be the same as with the size of the first and second LED electrode pads 27 and 29 or have a slightly large size.

On one surface of the TFT layer 11b on which the first and second TFT electrode pads 31 and 33 are formed, an insulation layer 30 may be stacked and formed. In this case, the first and second TFT electrode pads 31 and 33 may not be covered by the insulation layer 30 and exposed for a smooth metallic bonding with the first and second LED electrode pads 27 and 29.

The first and second TFT electrode pads 31 and 33 may be formed in a monolayer, and may be formed of any one from among Au, Cu, Ag, Ni, Ni/Au, Au/Ni, Ni/Cu, and Cu/Ni.

The first and second TFT electrode pads 31 and 33 may be patterned with a thin film on the TFT layer 11b through a deposition process such as sputtering. In this case, the thickness of the first and second TFT electrode pads 31 and 33 may be 0.1-1 mm.

Based on the first and second TFT electrode pads 31 and 33 being comprised of Au or Ni, the first and second TFT electrode pads 31 and 33 may be formed through an electrolytic plating process. When forming the first and second TFT electrode pads 31 and 33 through the electrolytic plating process, manufacturing costs may be reduced compared to the deposition process which require high temperature.

The multiple micro LEDs arrayed on a transfer substrate 870 (referring to FIG. 14) may be transferred from the transfer substrate 870 to the target substrate 880 by a transfer process. At this time, the first and second LED electrode pads 27 and 29 of each micro LED 20 may be easily bonded as the first and second LED electrode pads 27 and 29 are respectively alloyed through metallic bonding to the first and second TFT electrode pads 31 and 33 of the TFT layer 11b.

The TLP bonding process may be included in the transfer process. That is, the TLP bonding may be carried out simultaneously as the micro LED 20 is transferred or directly after the micro LED 20 is transferred to the target substrate 880.

The transfer process may be carried out in a predetermined chamber, the temperature within the chamber when performing PLT bonding may be set to a temperature of an extent the solder layers 27c and 29c can be melted, and in this state, the multiple micro LEDs 20 may be pressed toward the TFT layer 11b by a predetermined pressing member.

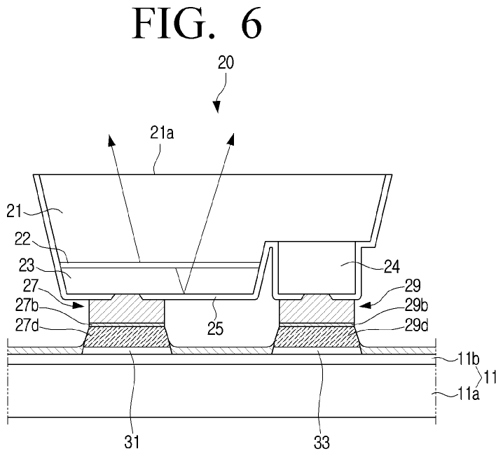

FIG. 6 is a cross-sectional diagram illustrating a junction structure between a micro LED and a TFT substrate according to an embodiment.

Referring to FIG. 6, alloy layers 27d and 29d which are a new metallic compound as the solder layers 27c and 29c of the first and second LED electrode pads 27 and 29, a portion of the barrier layers 27b and 29b of the first and second LED electrode pads 27 and 29, and a portion of the first and second TFT electrode pads 31 and 33 formed as a monolayer are melted together by PLT bonding.

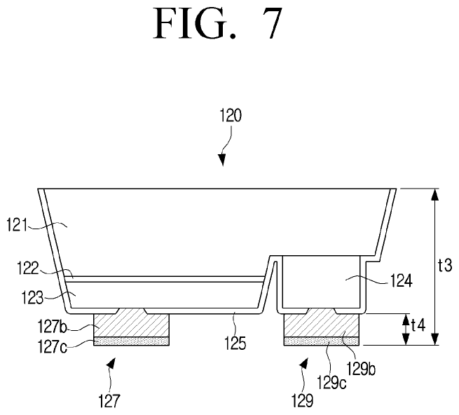

FIG. 7 is a cross-sectional diagram illustrating schematically a micro LED according to an embodiment.

Referring to FIG. 7, the first and second LED electrode pads 127 and 129 of the micro LED 120 may omit the filler layer. In this case, a thickness t4 of the first and second LED electrode pads 127 and 129 may have a thickness thinner by a thickness of the omitted filler layer than the thickness t2 of the first and second LED electrode pads 127 and 129 described above. The thickness of the barrier layers 127b and 129b of the first and second LED electrode pads 127 and 129 may be 0.05-2 μm, and the solder layers 127c and 129c may be 0.4-2 μm.

In this case, the thickness t4 of the first and second LED electrode pads 127 and 129 may be less than or equal to 40% relating to a total thickness t3 of the micro LED 120 to prevent a short between the electrode pads of the micro LED which are adjacent due to the solder layers 127c and 129c that are melted when performing the TLP bonding process.

The barrier layers 127b and 129b and the solder layers 127c and 129c of the first and second LED electrode pads 127 and 129 may be formed of the same material as with the barrier layers 27b and 29b and the solder layers 27c and 29c of the first and second LED electrode pads 27 and 29 shown in the above-described FIG. 4A.

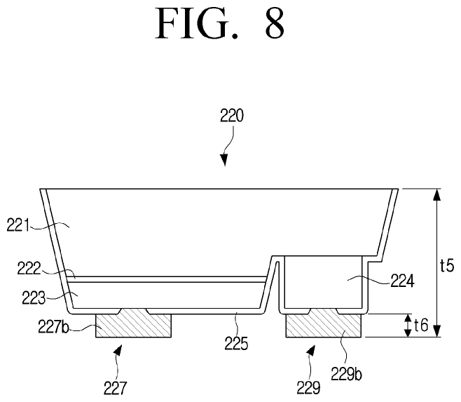

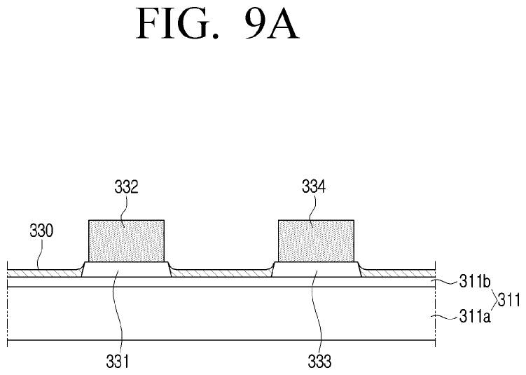

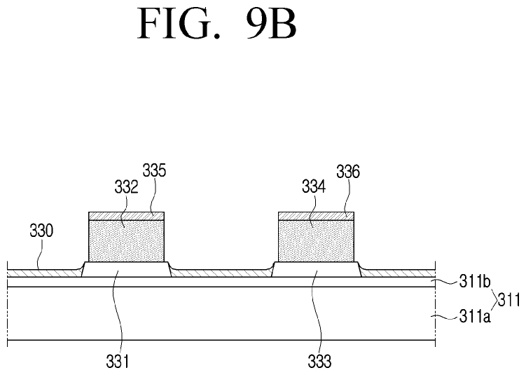

FIG. 8 is a cross-sectional diagram illustrating schematically a micro LED according to an embodiment. FIG. 9A is a cross-sectional diagram illustrating schematically a TFT substrate according to an embodiment. FIG. 9B is a diagram illustrating an example in which a capping layer is additionally formed on a solder layer of each TFT electrode pad shown in FIG. 9A according to an embodiment.

Referring to FIG. 8 the first and second LED electrode pads 227 and 229 of the micro LED 220 may be formed only of the barrier layers 227b and 229b as the filler layer and the solder layer are omitted unlike the first and second LED electrode pads 27 and 29 shown in the above-described FIG. 4A. In this case, the thickness of the barrier layers 227b and 229b may be formed to a thickness of 0.05-2 μm.

The barrier layers 227b and 229b of the first and second LED electrode pads 227 and 229 may be formed of the same material as with the solder layers 27b and 29b of the first and second LED electrode pads 27 and 29 shown in the above-described FIG. 4A.

Based on the solder layer being omitted from the first and second LED electrode pads 227 and 229, the first and second TFT electrode pads 331 and 333 may respectively include the solder layers 332 and 334 for the first and second LED electrode pads 227 and 229 to be bonded with the first and second TFT electrode pads 331 and 333 of the TFT layer 311b in a metallically bonded state respectively as in FIG. 9A.

In this case, the material and thickness of the first and second TFT electrode pads 331 and 333 may be formed to be the same in material and thickness of the first and second TFT electrode pads 31 and 33 shown in the above-described FIG. 5. In addition, the material and thickness of the solder layers 332 and 334 included in the first and second TFT electrode pads 331 and 333 may be formed to be the same in material and thickness of the solder layers 27c and 29c shown in the above-described FIG. 4A.

Referring to FIG. 9B, at the upper part of each of the solder layers 332 and 334, capping layers 335 and 336 respectively covering the solder layers 332 and 334 may be additionally stacked to prevent oxidization of the solder layers 332 and 334. In this case, the material of the capping layer may be Au, and the thickness may be less than or equal to 100 nm.

The thickness of the solder layers 332 and 334 may preferably be such that the total of adding the thickness of the solder layers 332 and 334 to a thickness t6 of each of the LED electrode pads 227 and 229 to prevent a short between the electrode pads of the micro LED which are adjacent due to the solder layers 332 and 334 that are melted when performing the TLP bonding process is less than or equal to 40% relating to a thickness t5 of the micro LED 220.

The first and second LED electrode pads 27 and 29 of the micro LED 20 shown in FIG. 4A may include the solder layers 27c and 29c, and the first and second LED electrode pads 127 and 129 of the micro LED 120 shown in FIG. 7 may also include the solder layers 127c and 129c. In this case, it may be possible for the first and second TFT electrode pads 31 and 33 of the TFT layer 11b to which the micro LEDs 20 and 120 are transferred to include the solder layers 332 and 334 as in FIG. 9A.

That is, the solder layer may be formed respectively at the first and second LED electrode pads which are bonded to each other and at the first and second TFT electrode pads. In this case, the total of the thickness of the solder layer of the first and second LED electrode pads and the thickness of the solder layer of the first and second TFT electrode pads may be a thickness of an extent a short between the electro pads of the micro LED which are adjacent due to the solder layer that is melted when performing the TLP bonding process may be prevented.

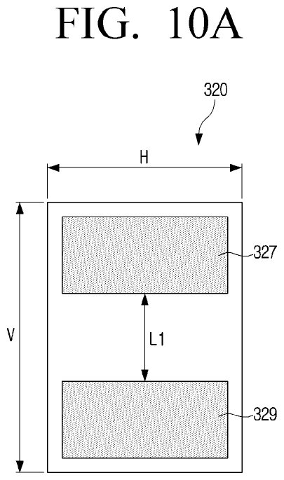

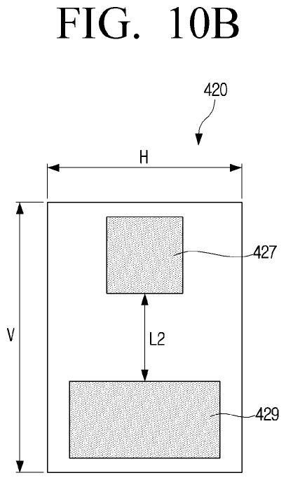

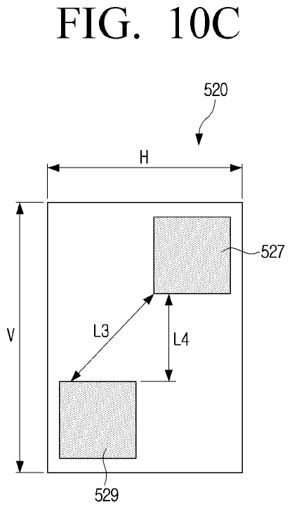

FIGS. 10A, 10B and 10C are diagrams illustrating various embodiments on two electrode pads of a micro LED according to an embodiment.

In addition, the micro LED may be produced into a rectangle shape, and a horizontal length H and a vertical length V may be 10-100 μm respectively as in FIG. 10A. In this case, the intervals between the micro LEDs 320 adjacent to one another which are transferred to the target substrate may be 20-70% of a horizontal length or a vertical length of the micro LED. The intervals between theses micro LEDs 320 may be determined based on a minimum distance L1 between the first and second LED electrode pads 327 and 329.

The two LED electrode pads 327 and 329 shown in FIG. 10A have been formed in the same size, but the two LED electrode pads 427 and 429 of the micro LED 420 may be formed to sizes different from each other as in FIG. 10B. The intervals between these micro LEDs 420 may be determined based on a minimum distance L2 between the first and second LED electrode pads 427 and 429.

In addition, the two LED electrode pads 327 and 329 shown in FIG. 10A may be disposed symmetrically to each other in a length direction of the micro LED 320, but the two LED electrode pads 527 and 529 of the micro LED 520 may be disposed adjacent to corners in a diagonal direction of the micro LED 520 as in FIG. 10C. In this case, a minimum distance between the two LED electrode pads 527 and 529 may be a minimum distance L3 along the diagonal direction of the micro LED 520 or a minimum distance L4 along the length direction of the micro LED 520.

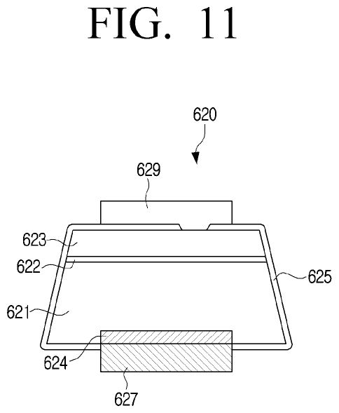

FIG. 11 is a cross-sectional diagram illustrating schematically a micro LED according to an embodiment.

The micro LED applied in the display module according to the disclosure may be the flip chip type as described above. However, the embodiment is not limited thereto and a micro LED of a vertical type may be applied as in FIG. 11.

Referring to FIG. 11, the micro LED 620 of the vertical type may be consecutively stacked with the n-type semiconductor layer 621, the light-emitting layer 622, and the p-type semiconductor layer 623. The n-type contact 624 may be stacked at the bottom surface of the n-type semiconductor layer 621, the first LED electrode pad 627 may be stacked at the bottom surface of the n-type contact 624, and a second electrode pad 629 may be stacked at an upper surface of the p-type semiconductor layer 623.

The first LED electrode pad 627 may be of a same structure with any one from among a structure of the first LED electrode pad 27 shown in the above-described FIG. 4A, a structure of the first LED electrode pad 127 shown in the above-described FIG. 7, and a structure of the first LED electrode pad 227 shown in the above-described FIG. 8.

The display module applied with the micro LED 620 of the vertical type as described above may configured such that the TFT layer formed on the target substrate to which the first LED electrode pad 627 is bonded may have a structure of the first TFT electrode pad 31 shown in the above described FIG. 5, or the same structure, material and thickness with the first TFT electrode pad 331 shown in the above-described FIG. 9A.

Accordingly, the first LED electrode pad 627 of the micro LED 620 of the vertical type may form the junction structure by metallic bonding with the first TFT electrode pad of the TFT layer.

The second LED electrode pad 629 may pass light without reduction in transmittance with a transparent electrode. The second LED electrode pad 629 as described may be formed of any one from among a ITO oxide, a IZO oxide, and a IZTO oxide having transparent characteristics.

In addition, the second LED electrode pad 629 may be formed of any one from among Ag, Al, and Au, and the thickness may be less than or equal to 5-20 nm so as to have the transparent characteristics. In this case, the micro LED 620 may further include the capping layer covering the second LED electrode pad 629.

The capping layer may protect the second LED electrode pad 629 while assisting so that the light generated from the light-emitting layer 622 is efficiently emitted to the outside through the upper surface of the micro LED 620. The capping layer may enhance light efficiency by raising an extraction rate of light emitted from the light-emitting layer and may be made of an inorganic film or an organic film, or made of the organic film in which inorganic particles are contained. The inorganic materials which may be used in the capping layer may be, for example, and without limitation, zinc oxide, titanium oxide, zirconium oxide, nitric oxide, niobium oxide, tantalum oxide, tin oxide, nickel oxide, indium nitride, gallium nitride, and the like. In addition, the organic materials which may be used in the capping layer may include acryl, polyimide, polyamide, and the like.

The display module applied with the micro LED 620 of the vertical type as described above may include the second TFT electrode pad to which the second LED electrode pad 629 is electrically connected through a lead wire (e.g., Au wire).

The micro LED 620 of the vertical type may be formed as a rectangle like the micro LED 20 of the flip chip type described above. In this case, the horizontal length and the vertical length of the micro LED 620 may respectively be 10-100 mm.

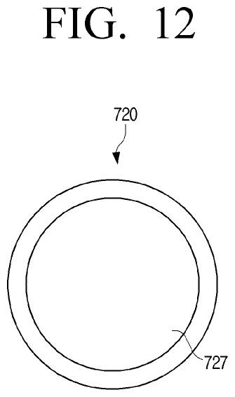

FIG. 12 is a diagram illustrating a micro LED of a vertical type formed in a circular shape according to an embodiment.

Referring to FIG. 12, the micro LED 720 of the vertical type may be formed in a circular shape. In this case, the first LED electrode pad 727 may be formed in the circular shape, and have an area of 20-90% relating to an area of one surface (a surface on which the n-type contact is formed) of the micro LED 720.

In the disclosure, the multiple micro LEDs arrayed on the transfer substrate 870 may be transported to the target substrate 880 through a laser transfer. A laser transfer device according to an embodiment will be described below with reference to the drawings.

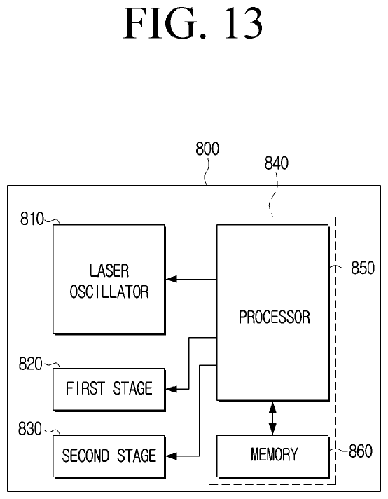

FIG. 13 is a block diagram illustrating schematically a laser transfer device according to an embodiment. FIG. 14 is a block diagram illustrating schematically a laser oscillator of a laser transfer device according to an embodiment.

Referring to FIG. 13, the laser transfer device 800 may include a laser oscillator 810, a first stage 820, a second stage 830, and a controller 840.

The laser oscillator 810 may transfer the multiple micro LEDs arrayed on the transfer substrate to the target substrate in a laser lift off (LLO) method.

Referring to FIG. 14, the laser oscillator 810 may include a laser generator 811 which generates a laser beam, an attenuator 812 for attenuating an intensity of the laser beam output from the laser generator, a homogenizer 813 forming the laser beam which passed the attenuator to have an overall uniform distribution, a mask 814 which limits the laser beam that passed the homogenizer to be irradiated in a certain pattern, and a projection lens (P-lens) 815 which reduces a pattern of the laser beam that passed the mask and irradiates to a transfer area of the transfer substrate. Multiple mirrors may be disposed between the attenuator 812 and the homogenizer 813, and between the homogenizer 813 and the mask 814 to change a pathway of the laser beam, respectively.

The laser generator 811 may apply a laser generator of various types such as an excimer laser and an ultraviolet (UV) laser according to a wavelength of the laser beam.

The attenuator 812 and the homogenizer 813 may adjust the intensity of the laser beam output from the laser generator 811 by being disposed on an irradiation pathway of the laser beam.

The homogenizer 813 may homogenize the laser beam as a whole based on using the excimer laser and a quality of the laser beam passing the mask 814 may be made uniform. The homogenizer 813 may make homogenization possible by dividing sunlight with acute changes in luminous intensity into a small light source and then overlapping at a surface which is to be the next target.

The mask 814 may be formed with multiple slits which form a certain pattern. The laser beam may appear in the certain pattern as it passes the multiple slits of the mask 814. The pattern of the mask may form a same pattern with the transfer pattern.

The P-lens 815 may focus a patterned laser beam which passed the mask 814 and irradiate toward the transfer substrate 870 loaded to the first stage 820 in the same pattern. In this case, the pattern of the laser beam irradiated to the transfer substrate 870 may correspond to a point at which multiple light-emitting diodes are disposed on the transfer substrate, for example, to each position of the multiple micro LEDs which are at a transfer position.

At the lower side of the P-lens 815, the transfer substrate 870 may be disposed with a certain interval. When the laser beam patterned through the P-lens 815 is irradiated to the transfer substrate 870, the multiple micro LEDs arrayed on the transfer substrate 870 may be transferred to the target substrate 880 with a certain interval at the lower side of the transfer substrate 870.

Referring to FIG. 13, the first stage 820 may be disposed with a certain interval at the lower side of the laser oscillator 810 when transferring. The first stage 820 may be moved to an X-axis, a Y-axis, and a Z-axis by a first driver which is not shown in the drawings. The first stage 820 may be configured to move along a guide rail which is vertically cross-disposed in the X-axis direction and Y-axis direction, and move in the Z-axis direction together with the guide rail.

The first stage 820 may be arrayed at a random position so as to not interfere with the laser oscillator 810 when operating loading and unloading of the transfer substrate 870.

The second stage 830 may be disposed with a certain interval at the lower side of the first stage 820 when transferring. The second stage 830 may be moved to the X-axis, the Y-axis, and the Z-axis by a second driver which is not shown in the drawings. The second stage 830 may be configured to move along the guide rail which is vertically cross-disposed in the X-axis direction and the Y-axis direction, and move in the Z-axis direction together with the guide rail.

The second stage 830 may be disposed at a random position so as to not interfere with the laser oscillator 810 when operating a loading and unloading of the target substrate 880.

The controller 840 may measure in real-time the position of the first and second stages 820 and 830 for the substrates to be disposed at accurate transfer positions. In this case, the controller 840 may identify the position of the first and second stages 820 and 830 based on a number of revolutions of a motor which moves each of the stages 820 and 830, a driving time, a movement speed of each of the stages 820 and 830, or the like.

Alternatively, the controller 840 may further include a position measurement sensor which measures in real-time a 3-dimensional position of the first and second stages 820 and 830. The position measurement sensor may include a first position sensor and a second position sensor which are provided for each of the first and second stages 820 and 830 respectively. The first position sensor may detect a 3-dimensional position of the first stage 820. The second position sensor may detect a 3-dimensional position of the second stage 830. The 3-dimensional position of the first and second stages 820 and 830 as described may be represented as a 3-dimensional coordinate.

The controller 840 may process, based on a rotation speed of the motor which moves each stage, the movement speed of the first and second stages 820 and 830 in real-time. Unlike the above, the controller 840 may further include a speed measurement sensor which senses the movement speed of each stage. In this case, the speed measurement sensor may be formed of first and second speed sensors which measure in real-time the movement speed of the first and second stages 820 and 830. The first speed sensor may measure in real-time the movement speed of the first stage 820. The second speed sensor may measure in real-time the movement speed of the second stage 830.

As described above, the movement speeds of the first and second stages 820 and 830 detected in real-time by the first and second speed sensors may be a base for controlling an irradiation timing of the laser beam.

The controller 840 may include a memory stored with characteristic information of multiple light-emitting diodes and a processor.

The processor may control the overall operation of the laser transfer device 800. That is, the processor may control each configuration by being electrically connected with the laser oscillator 810 and the first and second stages 820 and 830.

That is, the processor may determine a position to which the multiple light-emitting diodes are to be transferred respectively on the target substrate 880 based on the information stored in the memory, control the movements of the first and second stages 820 and 830 and move the transfer substrate 870 and the target substrate 880 to the transfer position, and control the laser oscillator 810 from the transfer position and irradiate the laser beam to a pre-set point of the transfer substrate 870.

Although it has been described as all configurations being controlled by a single processor, the disclosure is not limited thereto, and each configuration of the laser transfer device 800 may be controlled by using multiple independent processors. Here, the processor may include one or more from among a central processing unit (CPU), a controller, an application processor (AP), a communication processor (CP), or an ARM processor.

The memory may be implemented as at least one from among a flash memory type, a read only memory (ROM), a random access memory (RAM), a hard disk type, a multimedia card micro type, a card type memory (e.g., a secure digital (SD) memory or an extreme digital (XD) memory, etc.). The memory may be electrically connected with the processor and inter-transmit signals and information with the processor. The memory may store information obtained by a flatness measurement sensor 60, the position measurement sensor, and the speed measurement sensor, and the processor may access the information stored in the memory.

The multiple micro LEDs arrayed on the transfer substrate 870 may be transferred to the target substrate 880 through the laser transfer device 800, but it may also be possible to transfer the multiple micro LEDs arrayed on the transfer substrate 870 to the target substrate 880 by a pick and place method or a roll based multi-transferring method without being limited to the laser transfer method.

A large format display (LFD) may be manufactured by using the display module according to the disclosure in multiple and arraying in a tile form. In this case, a pitch between pixels arrayed at an outermost side of the display modules adjacent to one another may be maintained to be the same as a pitch between the pixels in a single display module and a seam may be prevented from appearing in-between each display module.

In addition, the display module according to the disclosure may form a side surface wiring of a thin film at an edge part of the display module to electrically connect the TFT circuit of the TFT layer formed at the front surface with a driving circuit formed at the back surface, and the like.

While the disclosure has been illustrated and described with reference to various example embodiments thereof, it will be understood that the various example embodiments are intended to be illustrative, not limiting. It will be understood by those skilled in the art that various changes in form and details may be made therein without departing from the true spirit and full scope of the disclosure, including the appended claims and their equivalents.

What is claimed is:

1. A display module, comprising:
a thin film transistor (TFT) substrate comprising:
a glass substrate,
a TFT layer provided at a front surface of the glass substrate and comprising a TFT electrode pad, and
a driving circuit provided at a rear surface of the glass substrate and configured to drive the TFT layer;
at least one light-emitting diode (LED) comprising at least one LED electrode pad; and
a junction structure provided between the at least one LED electrode pad and the TFT electrode pad,
wherein the junction structure is formed in a metallically bonded state.

2. The display module of claim 1, wherein at least one of the LED electrode pad and the TFT electrode pad further comprise a solder layer, and
wherein the junction structure comprises a metallic compound which is generated as the LED electrode pad and the TFT electrode pad are melted together with the solder layer.

3. The display module of claim 2, wherein the LED electrode pad comprises a barrier layer comprising at least one from among Au, Ni, Ti, Cr, Pd, TiN, Ta, TiW, TaN, AlSiTiN, NiTi, TiBN, ZrBN, TiAlN, and TiB₂, and
wherein the TFT electrode pad comprises at least one from among Au, Cu, Ag, Ni, Ni/Au, Au/Ni, Ni/Cu, and Cu/Ni.

4. The display module of claim 3, wherein the solder layer comprises Sn or In.

5. The display module of claim 4, wherein a capping layer is provided at an upper part of the solder layer, and
wherein the capping layer comprises Au.

6. The display module of claim 3, wherein the solder layer comprises at least two from among Sn, Ag, In, Cu, Ni, Au, Bi, Al, Zn, and Ga.

7. The display module of claim 6, wherein a capping layer is provided at an upper part of the solder layer, and
wherein the capping layer comprises Au.

8. The display module of claim 3, wherein the LED electrode pad further comprises a filler layer provided on the barrier layer,
wherein the filler layer is provided between a semiconductor layer of the at least one LED and the barrier layer, and
wherein the filler layer comprises one from among Au, Cu, Ni, and Al.

9. The display module of claim 8, wherein a thickness of the LED electrode pad is less than or equal to 40% of a thickness of the at least one LED.

10. The display module of claim 9, wherein a thickness of the barrier layer is about 0.05 μm to about 2 μm,
wherein a thickness of the solder layer is about 0.4 μm to about 2 μm, and
wherein a thickness of the filler layer is about 1 μm to about 5 μm.

11. The display module of claim 2, wherein a thickness of the TFT electrode pad is about 0.1 μm to about 1 μm.

12. The display module of claim 1, wherein an interval between LEDs adjacent to one another is about 20 to about 70% of a size of the at least one LED.

13. The display module of claim 12, wherein the TFT electrode pad is provided on the TFT layer.

14. The display module of claim 1, wherein the TFT electrode pad comprises Au or Ni, and
wherein the TFT electrode pad is formed on the TFT layer in an electrolytic plating method.

15. A display module, comprising:
a thin film transistor (TFT) substrate comprising:
a glass substrate,
a TFT layer provided at a front surface of the glass substrate, and
a driving circuit provided at a rear surface of the glass substrate and configured to drive the TFT layer;
a plurality of light-emitting diodes (LEDs); and
a pair of LED electrode pads provided for each LED of the plurality of LEDs;
wherein each of the pair of LED electrode pads comprises a junction structure in a metallically bonded state; and
wherein an interval between LEDs of the plurality of LEDs adjacent to one another is determined based on a minimum distance between the pair of LED electrode pads.
